(19) United States
(12) Patent Application Publication
(10) Pub. No.: US 2024/0189854 A1
(43) Pub. Date: Jun. 13, 2024

(54) DISPENSER AND INK APPLICATION EQUIPMENT HAVING SAME

(71) Applicant: LG ELECTRONICS INC., Seoul (KR)

(72) Inventors: Hyucksam KWON, Seoul (KR); Changwoo KANG, Seoul (KR); Intack YEO, Seoul (KR); Yoonseok CHEONG, Seoul (KR)

(73) Assignee: LG ELECTRONICS INC., Seoul (KR)

(21) Appl. No.: 18/286,207

(22) PCT Filed: Apr. 8, 2022
(86) PCT No.: PCT/KR2022/005155

§ 371 Date: Oct. 9, 2023

(30) Foreign Application Priority Data
Apr. 9, 2021 (KR) 10-2021-0046715

(51) Int. Cl. B05C 5/02; B05C 9/10; B05C 9/12; H01L 27/146

(52) U.S. Cl. CPC B05C 5/0225; B05C 9/10; B05C 9/12; H01L 27/14685

(57) ABSTRACT

A dispenser comprises: a nozzle having a nozzle hole; a connector to which the nozzle is coupled; a syringe detachably coupled to the connector, having a space in which the ink is contained, and provided with a plunger; and a tube assembly to which the syringe is detachably coupled and which injects air that moves the plunger, into the syringe.

### TECHNICAL FIELD

The present disclosure relates to a dispenser and an ink application apparatus having the same.

### BACKGROUND ART

In the case of mobile devices, efforts are being made to minimize or eliminate camera and speaker holes in order to expand the front display area, and in particular, Hole In Display (HID) technology, which processes holes in the display to minimize the camera area, has been developed.

In mobile devices, camera clarity can be reduced due to light leakage, where light from the display panel leaks through the side of the hole and this problem can be prevented by minimizing light leakage by coating the side of the hole with a thin film of resin.

An example that can supply a small amount of liquid to the hole side of an electronic device may be a small amount of liquid dispenser disclosed in Korean Patent Publication No. 10-2017-0008200 A (published on Jan. 23, 2017), and the small amount of liquid dispenser includes a upstream passage portion, a middle passage portion, and a downstream passage portion, and includes a liquid passage which is a passage portion capable of expanding and contracting to increase or decrease the internal volume of the intermediate passage portion, and a liquid supply portion which supplies liquid to the nozzle through the liquid passage, passage deformation mechanism which deforms the intermediate passage portion to increase or decrease the internal volume of the intermediate passage portion, and a controller.

### DISCLOSURE

### Technical Problem

This embodiment provides a dispenser in which a replaceable syringe is provided between the tube assembly and the connector, has a simple structure and is easy to precisely control by pneumatic pressure of the connector, and an ink application apparatus having the same.

### Technical Solution

An ink application apparatus including a dispenser according to the present embodiment may include a tornado cleaner, which performs a process of suspending and suctioning foreign substances by supplying pneumatic pressure to a hole formed in an electronic device component; a plasma processor that performs a process of plasma processing the electronic device components; and a dispenser for applying ink to a hole of electronic device components on which the tornado cleaner process and the plasma processor process have been performed.

A dispenser according to the present embodiment includes a nozzle with a nozzle hole formed thereon; a connector to which the nozzle is coupled; a syringe detachably coupled to the connector, forming a space containing ink, and having a plunger; and a tube assembly to which the syringe is detachably coupled and which injects air that moves the plunger into the syringe.

The connector may include an elastic member with an inner space formed therein; an inlet channel which guides ink in the space into the inner space; an outlet channel guiding ink in the inner space to the nozzle hole; and a housing surrounding the elastic member, an outer space may be formed between the housing and the elastic member, and an air inlet channel may be formed in the housing to guide air into the outer space.

The diameter of the nozzle hole may be 50 μm to 200 μm.

The nozzle may be made of SUS material.

The nozzle hole may have an outlet through which ink flows, and the outlet may have an inclination angle forming an acute angle with the longitudinal direction of the nozzle hole.

The nozzle hole diameter may be 1/100 to 1/1000 times the inlet channel diameter.

The elastic member may be a chemical-resistant rubber tube.

The housing may include an inlet channel through-hole through which the inlet channel passes, and an outlet channel through-hole through which the outlet channel passes.

The upper end of the inlet channel may be exposed above the housing.

The air inlet channel may be perpendicular to the opening direction of the outlet channel through-hole.

The tube assembly may include a tube; and a tube connector to which the tube is connected and to which the syringe is detachably coupled.

The tube connector may include a syringe coupling portion to which the syringe is coupled; and a hollow portion that guides the fluid supplied through the tube to the syringe.

An O-ring may be disposed on the outer circumferential surface of the hollow portion to seal between the outer circumferential surface of the hollow portion and the inner circumferential surface of the syringe.

The dispenser may further include a first pneumatic generator connected to a first pneumatic line connected to the tube assembly; a first pressure gauge measuring the pressure of the first pneumatic line; a first valve installed in the first pneumatic line; a second pneumatic generator connected to a second pneumatic line connected to the air inlet channel; a second pressure gauge measuring the pressure of the second pneumatic line; a second valve installed in the second pneumatic line; and a main controller that controls the first valve according to the pressure value of the first pressure gauge and controls the second valve according to the pressure value of the second pressure gauge.

### Advantageous Effect

According to an embodiment of the present disclosure, the connector can adjust the discharge amount of ink between the syringe and the nozzle, and the response speed can be improved by adjusting the pneumatic pressure of the connector.

Additionally, the syringe can be easily replaced by the syringe coupling portion formed on the tube connector of the tube assembly.

Additionally, the upper end of the inlet channel is exposed above the housing, making it easy to replace the syringe.

### DESCRIPTION OF DRAWINGS

FIG. 1 is a view illustrating when a dispenser according to this embodiment applies ink to a hole in an electronic device compartment;

FIG. 2 is a view illustrating an example of ink applied by a dispenser according to this embodiment;

FIG. 3 is a view illustrating a state where the syringe of the dispenser according to this embodiment is separated;

FIG. 4 is a view illustrating a dispenser according to this embodiment;

FIG. 5 is a view illustrating when the connector of the dispenser according to this embodiment does not supply ink;

FIG. 6 is a view illustrating when the connector of the dispenser according to this embodiment supplies ink;

FIG. 7 is a plan view illustrating ink application apparatus including a dispenser according to this embodiment;

FIG. 8 is a view illustrating a tornado cleaner according to this embodiment; and

FIG. 9 is a perspective view illustrating an application mechanism according to this embodiment.

### BEST MODE

Hereinafter, specific embodiments of the present disclosure will be described in detail along with the drawings.

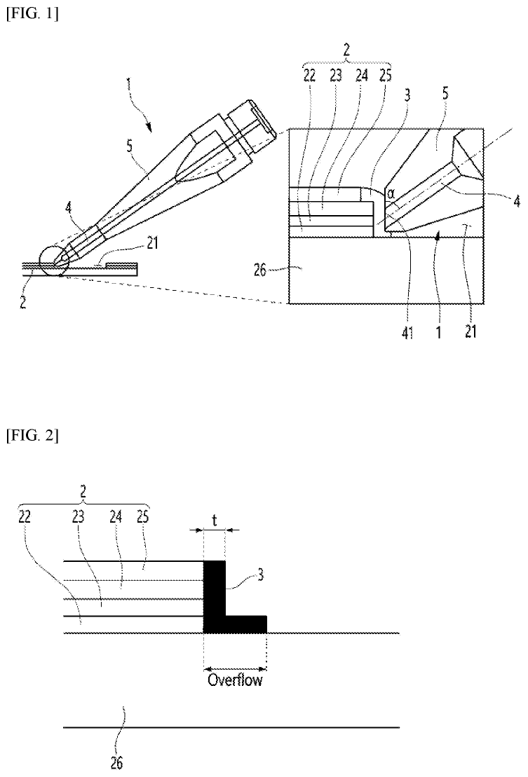

FIG. 1 is a view illustrating when a dispenser according to this embodiment applies ink to a hole in an electronic device compartment; and FIG. 2 is a view illustrating an example of ink applied by a dispenser according to this embodiment.

As illustrated in FIG. 1, the dispenser 1 can apply the ink 3 into the hole 21 formed in the electronic device component 2.

An example of the electronic device component 2 may include an Optical Clear Adhesive (OCA) film 22, a polarizer 23, a panel 24, and a metal cover 25.

The electronic device component 2 is a component of an electronic device, and may be, for example, a component of a mobile terminal.

When the ink 3 is applied to this electronic device component 2, a thin film is formed along the circumference of the hole 21 and then can be assembled with other components of the mobile terminal, and the camera of the mobile terminal can head towards the hole 21.

The OAC film 22 may be formed on one side of the cover glass 26 and may be located between the cover glass 26 and the polarizing film 23.

The OCA film 22, polarizer 23, panel 24, and metal cover 25 may be formed sequentially.

A hole 21 for a camera may be formed in each of the OCA film 22, the polarizer 23, the panel 24, and the metal cover 25. An example of the hole 21 may have a size of 3.75 mm.

The electronic device component 2 may have ink 3 applied to the hole 21 to minimize light leakage from the camera, and the applied ink 3 may form a thin film along the circumference of the hole 21.

The ink 3 can seal between the cover class 26 and the OAC film 22, between the OCA film 22 and the polarizer 23, between the polarizer 23 and the panel 24, and between the panel 24 and the metal cover (25), and the light generated from the camera may not leak through between the cover class 26 and the OAC film 22, between the OCA film 22 and the polarizer 23, between the polarizer 23 and the panel 24, and between the panel 24 and the metal cover 25.

An example of the ink 3 may be black ink, and the dispenser 1 may apply the ink 3 to the circumference (side) of the hole 21.

As illustrated in FIG. 2, the ink 3 is preferably formed to an appropriate width t in the hole 21 and is preferably applied to the cover glass 26 to form an appropriate overflow.

Here, the appropriate width t is preferably 20 μm to 50 μm, and the overflow is preferably 350 μm or less.

For the application process of the ink 3 as described above, the dispenser 1 may include a nozzle 5 for applying the ink 3 to the hole 21 of the electronic device component 2, and the nozzle 5 may be formed with a nozzle hole 4 through which the ink 3 passes.

The nozzle hole 4 may be formed through the nozzle 5. As illustrated in FIG. 1, the nozzle hole 4 may include an outlet 41 through which the ink 3 flows.

The nozzle 4 is preferably configured so that the ink 3 is formed around the circumference (side) of the hole 21 with a width t of 20 μm to 50 μm, and the overflow is 350 μm or less, and the shape of the nozzle 4 may be a shape corresponding to the circumference (side) of the hole 21.

The nozzle 5 is designed to thinly apply the ink 3 to the circumference (side) of the hole 21, so that the outlet 41 of the nozzle hole 4 is not perpendicular to the opening direction of the nozzle 4, and the outlet 41 of the nozzle hole 4 may be formed in a shape having an acute inclination angle α with the opening direction of the nozzle 4.

The nozzle 5 may be manufactured so that the outlet 41 of the nozzle hole 4 applies the ink 3 in a horizontal direction. In a state where the dispenser 1 is tilted at a predetermined angle, the lower portion of the nozzle 5 can be cut vertically, the outlet 41 of the nozzle hole 4 can have a vertical surface, and the nozzle 5 can apply the ink 3 to the side.

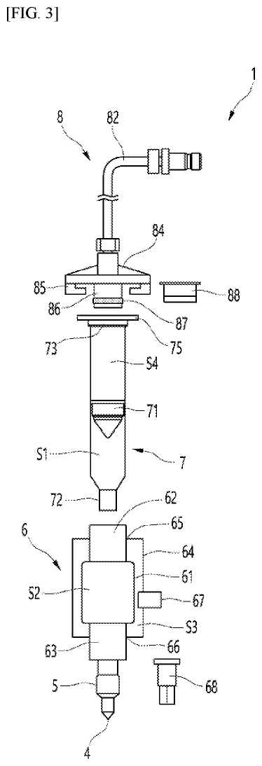

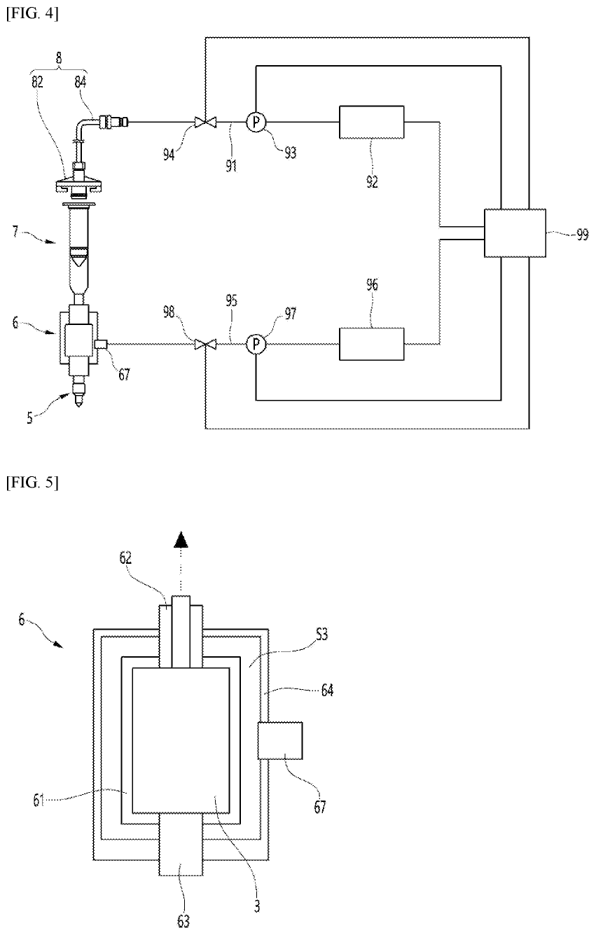

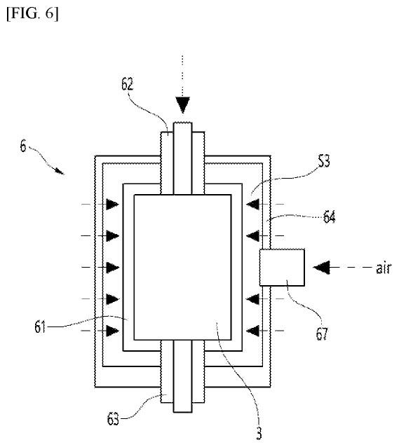

FIG. 3 is a view illustrating a state where the syringe of the dispenser according to this embodiment is separated; FIG. 4 is a view illustrating a dispenser according to this embodiment; FIG. 5 is a view illustrating when the connector of the dispenser according to this embodiment does not supply ink; and FIG. 6 is a view illustrating when the connector of the dispenser according to this embodiment supplies ink;

The dispenser 1 may include a nozzle 5 with a nozzle hole 4 formed, a connector 6 to which the nozzle 5 is coupled, a syringe 7 detachably coupled to the connector 6, having a space S1 into which the ink 3 is contained, and equipped with a plunger 71; and a tube assembly 8 to which the syringe 7 is detachably coupled and which injects air that moves the plunger 71 into the syringe 7.

An inner space S2 may be formed in the connector 6 to accommodate the ink 3 supplied from the syringe 7, and an outer space S3 may be formed outside the inner space S2 for pressurizing the ink 3 in the inner space S1.

The inner space S2 and the outer space S3 may be formed by being partitioned from each other. The inner space S2 and the outer space S3 may be partitioned by an elastic member 61.

The dispenser 1 may be an ultra-thin dispenser using Fine Air Dispense (FAD). The dispenser 1 can quickly apply a small amount of ink 3 to the hole 21 of the electronic device component 2 by utilizing FAD.

An example of the connector 6 may include an elastic member 61 in which an inner space S2 is formed, an inlet channel 62 that guides the ink 3 in the space S1 to the inner space S2, an outlet channel 63 that guides the ink 3 in the inner space S2 to the nozzle hole of the nozzle 5, and a housing 64 surrounding the elastic member 61.

The ink 3 guided from the inner space S2 of the connector 6 to the nozzle hole 4 may pass through the nozzle hole 4 and be applied to the hole 21 of the electronic device component 2.

The ratio of the size of the nozzle hole 4 and the portion of the syringe 7 that receives the ink 3 may be 1:100 or less, and in this case, the dispenser 1 can apply a small amount of ink 3. To this end, the diameter of the nozzle hole 4 may be 1/100 to 1/1000 times the diameter (inner diameter) of the inlet channel 63.

The diameter of the nozzle hole 4 may be 50 μm to 200 μm, preferably 100 μm.

The nozzle 5 may be made of SUS material. The nozzle 5 can also be made of a ceramic material, but if it is made of a ceramic material, it has the disadvantage of being vulnerable to impact, making it easy to break, and making it difficult to secure mass production.

The elastic member 61 may have a hollow shape. The elastic member 61 may be deformed by fluid (for example, air) supplied between the elastic member 61 and the housing 64, and if the fluid pressure between the elastic member 61 and the housing 64 is low, the elastic member can be restored to the original shape thereof. An example of the elastic member 61 may be a chemical-resistant rubber tube.

The inlet channel 62 may be formed on the upper portion of the elastic member 61 or may be connected to the upper portion of the elastic member 61. An example of the inlet channel 62 may be formed by a hollow portion protruding from the upper portion of the elastic member 61. Another example of the inlet channel 62 may be formed by a tube or pipe coupled to the upper portion of the elastic member 61.

The outlet 72 of the syringe 7 may be communicated with the inlet channel 62.

The outlet channel 63 may be formed in the lower portion of the elastic member 61 or connected to the lower portion of the elastic member 61. An example of the outlet channel 63 may be formed by a hollow portion protruding from the lower portion of the elastic member 61. Another example of the outlet channel 63 may be formed by a tube or pipe coupled to the lower portion of the elastic member 61.

The nozzle hole of the nozzle 5 may communicate with the outlet channel 63.

The housing 64 may be larger than the elastic member 61 and may surround the elastic member 61 on the outside of the elastic member 61. The housing 64 may be formed of a material harder than the elastic member 61.

An outer space S3 may be formed between the housing 64 and the elastic member 61.

The housing 64 may be formed with an inlet channel through-hole 65 through which the inlet channel 62 passes and an outlet channel through-hole 66 through which the outlet channel 67 passes.

The upper end of the inlet channel 62 can be exposed over the housing 64, and the syringe 7 can be easily coupled to the connector 6.

The lower end of the outlet channel 67 may be exposed below the housing 64, and the nozzle 5 may be easily coupled to the connector 6.

An air inlet channel 67 may be formed in the housing 64 to guide air to the outer space.

The air inlet channel 67 may be perpendicular to the opening direction of the outlet channel through-hole 66. The outlet channel through-hole 66 may be open in the vertical direction, and the air inlet channel 67 may be formed to be long in the horizontal direction.

The syringe 7 may be a cartridge that is replaced when the ink 3 is exhausted. The syringe 7 may be detachably coupled to each of the connector 6 and the tube assembly 8.

The syringe 7 may include an outlet 72 coupled to the connector 6. The outlet 72 may be in communication with the inlet channel 62 of the connector 6. The ink 3 may be accommodated between the plunger 71 and the outlet 72. The space between the plunger 71 and the outlet 72 may be defined as a space S1 in which the ink 3 is accommodated.

The syringe 7 may include an inlet 73 coupled to the tube assembly 8. When the syringe 7 is coupled to the tube assembly 8, the inlet 73 may communicate with the interior of the tube assembly 8.

The space between the inlet 73 of the syringe 7 and the plunger 71 may be a pressurized space S4 filled with a fluid (for example, air) that moves the plunger 71.

When air is supplied through the tube assembly 8, the air may flow into the pressurization space S4 through the inlet 73 and pressurize the plunger 71.

A fastening portion 75 that can be detachably coupled to the tube assembly 8 may be formed on the upper portion of the syringe 7.

The fastening portion 75 may protrude from the outer circumference of the syringe 7 in the radial direction of the syringe 7.

The syringe 7 may be coupled to each of the connector 6 and the tube assembly 8 between the connector 6 and the tube assembly 8. When all of the ink 3 is exhausted, the syringe 7 can be separated from the connector 6 and the tube assembly 8, respectively.

Tube assembly 8 may further include a tube 82 and a tube connector 84.

Fluid for pressurizing the plunger 71 may be supplied to the tube 82.

One end of the tube 82 may be connected to the tube connector 84.

The tube 82 may be an adapter tube through which fluid can pass.

The tube connector 84 can be connected to the tube 82 and the syringe 7 can be detachably coupled thereto.

The tube connector 84 may include a syringe coupling portion 85 to which the syringe 7 is coupled.

The fastening portion 75 of the syringe 7 may be interpolated into the syringe coupling portion 85, and the syringe 7 may be coupled to the tube connector 84.

The tube connector 84 may include a hollow portion 86 that guides the fluid supplied through the tube 82 to the pressurized space S4 of the syringe 7.

A portion of the hollow portion 86 may be formed inside the syringe coupling portion 85.

A passage through which fluid passes may be formed inside the hollow portion 86.

The hollow portion 86 may be formed in a cylindrical shape.

One end of the tube 82 may be inserted into the upper portion of the hollow portion 86.

When the syringe 7 and the syringe coupling portion 85 are coupled, the lower portion of the hollow portion 86 may be inserted into the pressurized space S4 of the syringe 7.

An O-ring 87 that can seal between the outer circumferential surface of the hollow portion 86 and the inner circumferential surface of the syringe 7 can be placed on the outer circumference of the portion of the hollow portion 86 inserted into the pressurized space S4 of the syringe 7.

As illustrated in FIG. 4, the dispenser 1 may include a first pneumatic generator 92 connected to the first pneumatic line 91 connected to the tube assembly 8, a first pressure gauge 93 measuring the pressure of the first pneumatic line 91, a first valve 94 installed on the first pneumatic line 91, a second pneumatic pressure generator 96 connected to the second pneumatic line 95 connected to the air inlet channel 67, a second pressure gauge 97 measuring the pressure of the second pneumatic line 95, and a second valve 98 installed on the second pneumatic line 95.

The dispenser 1 may further include a main controller 99. The main controller 99 may control the first valve 94 according to the pressure value of the first pressure gauge 93. The main controller 99 can control the second valve 98 according to the pressure value of the second pressure gauge.

The dispenser 1 can fill the ink 3 in the inner space S2 of the elastic member 61 by the pressure of the fluid supplied from the tube assembly 8, and then adjust the pressure of the fluid injected into the outer space S3, and discharge the ink 3 into the nozzle 4 through the force of the elastic member 61 to contract.

The dispenser 1 can supply the ink 3 to the nozzle 4 while the main controller 99 compensates for pressure in real time.

The dispenser 1 as described above may have a faster response speed compared to the case where the ink 3 of the syringe 7 is directly supplied to the nozzle 5.

Reference numeral 68 illustrated in FIG. 3 is a nozzle cap that blocks the nozzle hole 4 of the nozzle 5, before the nozzle 5 applies ink 3 to the hole 21 of the electronic device component 2, the nozzle cap can be separated from the nozzle 5.

Reference numeral 88 illustrated in FIG. 3 is a head cap that blocks the hollow portion 86 of the tube assembly 8, and the head cap can be separated from the tube connector 84 before coupling the syringe 7 to the tube connector 84.

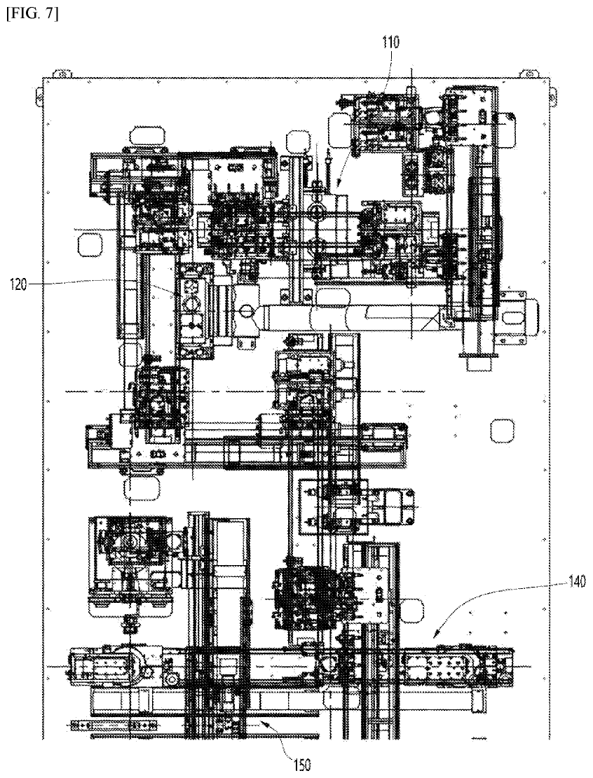

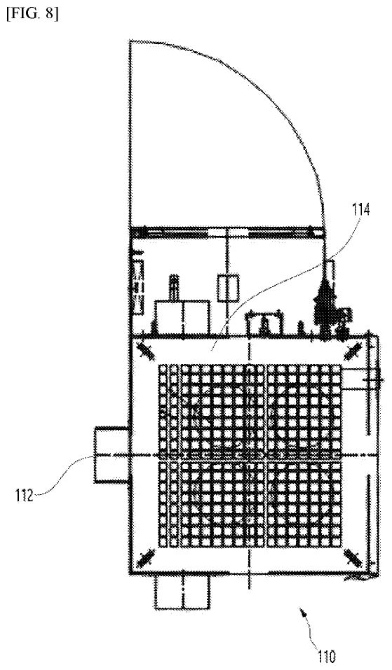

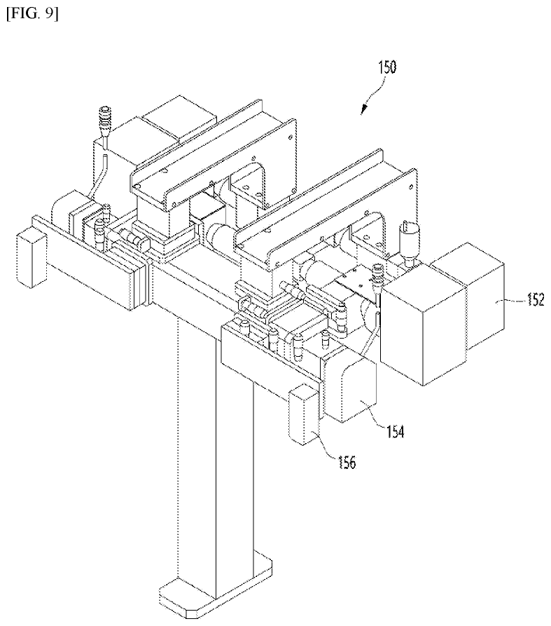

FIG. 7 is a plan view illustrating ink application apparatus including a dispenser according to this embodiment; FIG. 8 is a view illustrating a tornado cleaner according to this embodiment; and FIG. 9 is a perspective view illustrating an application mechanism according to this embodiment.

As illustrated in FIG. 7, ink application apparatus including a dispenser may include a tornado cleaner 110, a plasma processor 120, and a dispenser 1.

The tornado cleaner 110 can perform a process of suspending and suctioning foreign substances by supplying pneumatic pressure to the hole 21 formed in the electronic device component 2. The tornado cleaner 110 may include a blower 112 that supplies high-pressure air (pneumatic pressure) to the hole 21 formed in the electronic device component 2, and a suction device 114 that suctions foreign substances suspended by air supplied from the blower 112 to the hole 21.

The plasma processor 120 (plasma cleaner) can perform a process of plasma processing the electronic device component 2. The plasma processor 120 may include a plasma generator that generates plasma.

An ink application apparatus including a dispenser may further include an application mechanism 150.

The application mechanism 150 may include dispenser 1. The dispenser 1 can apply the ink 3 to the hole 2 of the electronic device component 1 where the process of the tornado cleaner 110 and the process of the plasma processor 120 have been performed. The dispenser 1 may be the dispenser illustrated in FIGS. 3 to 5, and detailed description thereof will be omitted to avoid redundant description.

The application mechanism 150 may include a dispenser holder on which the connector 6 of the dispenser 1 and the syringe 7 are supported.

An ink application apparatus including a dispenser may further include a dispensing lane 140 along which the plasma-processed electronic device component 2 moves.

A single stage (not illustrated) may be disposed in the dispensing lane 140. The application mechanism 150 may include a drive mechanism including a motor that moves the stage or the dispenser 1.

An encoder may be built into the motor, and the application mechanism 150 may check the value of the encoder, allowing the dispenser 1 to discharge the ink 3, and further improve the response speed.

The stage driving mechanism can correct the stage in θ, X, and Y.

The electronic device component 2 may be moved and rotated along the dispensing lane 140 while placed on the stage.

The application mechanism 150 may include a vision camera, a displacement sensor 152, and a curing device 153.

The vision camera can sense the position or angle of the electronic device component 2 and track the position or angle of the electronic device component 2. The vision camera can track the hole 21 formed in the electronic device component 2, and the dispenser 1 can apply the ink 3 according to the shape recognized by the vision camera.

An example of the displacement sensor 152 may be a linear variable differential transformer (LVDT).

The curing device 153 irradiates ultraviolet rays to the hole 21 of the electronic device component 2 to cure the ink 3 after the dispenser 1 applies ink 3 to the hole 21 of the electronic device component 2, and for example, the curing device can be a UV Cure System.

With the electronic device component 2 placed on the stage, alignment, height measurement, ink application, and curing can be performed.

The above description is merely an illustrative explanation of the technical idea of the present disclosure, and various modifications and variations will be possible to those skilled in the art without departing from the essential characteristics of the present disclosure.

Accordingly, the embodiments disclosed in the present disclosure are not intended to limit the technical idea of the present disclosure, but are for illustrative purposes, and the scope of the technical idea of the present invention is not limited by these embodiments.

The scope of protection of the present disclosure should be interpreted in accordance with the claims below, and all technical ideas within the equivalent scope should be construed as being included in the scope of rights of the present disclosure.

1. A dispenser comprising:
a nozzle comprising a nozzle hole;
a connector to which the nozzle is coupled;
a syringe detachably coupled to the connector, wherein the syringe comprises a plunger and defines a space therein configured to hold ink; and
a tube assembly detachably coupled to the syringe and configured to inject air to cause the plunger to move in the syringe,
wherein the connector includes:
an elastic member with an inner space formed therein;
an inlet channel configured to allow ink to flow from the space of the syringe into the inner space;
an outlet channel configured to allow ink to flow from the inner space to the nozzle hole; and
a housing surrounding the elastic member,
wherein an outer space is defined between the housing and the elastic member, and
wherein an air inlet channel is formed at the housing to allow air to pass into the outer space.

2. The dispenser of claim 1,
wherein the nozzle is made of Steel Use Stainless (SUS) material.

3. The dispenser of claim 1,
wherein a surface at an outlet of the nozzle hole forms an acute angle with respect to a longitudinal direction of the nozzle hole.

4. The dispenser of claim 1,
wherein a diameter of the nozzle hole is 1/100 to 1/1000 times a diameter of the inlet channel.

5. The dispenser of claim 1,
wherein the elastic member is a chemical-resistant rubber tube.

6. The dispenser of claim 1,
wherein the housing includes:
an inlet channel through-hole configured to accommodate the inlet channel, and
an outlet channel through-hole configured to accommodate the outlet channel.

7. The dispenser of claim 6,
wherein an upper end of the inlet channel extends above the housing.

8. The dispenser of claim 6,
wherein the air inlet channel is perpendicular to the outlet channel through-hole.

9. The dispenser of claim 1,
wherein the tube assembly includes:
a tube; and
a tube connector to which the tube is connected and configured to be detachably coupled to the syringe.

10. The dispenser of claim 9,
wherein the tube connector includes:
a syringe coupling portion configured to be coupled to the syringe; and
a hollow portion configured to allow fluid supplied through the tube to flow into the syringe,
wherein an O-ring is disposed on an outer circumferential surface of the hollow portion to provide a seal between the hollow portion and an inner circumferential surface of the syringe.

11. An ink application apparatus including a dispenser, comprising:
a tornado cleaner configured to perform a process of suspending and suctioning foreign substances by supplying pneumatic pressure to a hole formed in an electronic device component;
a plasma processor configured to perform a process of plasma processing the electronic device components; and
a dispenser for applying ink to the hole of the electronic device components,
wherein the dispenser includes:
a nozzle comprising a nozzle hole;
a connector to which the nozzle is coupled;
a syringe detachably coupled to the connector, wherein the syringe comprises a plunger and defines a space therein configured to hold ink; and
a tube assembly detachably coupled to the syringe and configured to inject air to cause the plunger to move in the syringe,
wherein the connector includes:
an elastic member with an inner space formed therein;
an inlet channel configured to allow ink to flow from the space of the syringe into the inner space;
an outlet channel configured to allow ink to flow from the inner space to the nozzle hole; and
a housing surrounding the elastic member, and
wherein the elastic member is a chemical-resistant rubber tube.

12. The ink application apparatus including a dispenser of claim 11,
wherein a surface at an outlet of the nozzle hole forms an acute angle with respect to a longitudinal direction of the nozzle hole.

13. The ink application apparatus including a dispenser of claim 11,
wherein the tube assembly includes:
a tube; and
a tube connector to which the tube is connected and configured to be detachably coupled to the syringe.

14. The ink application apparatus including a dispenser of claim 13,
wherein the tube connector includes:
a syringe coupling portion configured to be coupled to the syringe; and
a hollow portion configured to allow fluid supplied through the tube to flow into the syringe, and
wherein an O-ring is disposed on an outer circumferential surface of the hollow portion to provide a seal between the hollow portion and an inner circumferential surface of the syringe.

15. The ink application apparatus including a dispenser of claim 11, further comprising:
a first pneumatic generator connected to a first pneumatic line which is connected to the tube assembly;
a first pressure gauge configured to measure a pressure of the first pneumatic line;
a first valve installed on the first pneumatic line;
a second pneumatic generator connected to a second pneumatic line which is connected to the air inlet channel;
a second pressure gauge configured to measure a pressure of the second pneumatic line;
a second valve installed on the second pneumatic line; and
a main controller configured to control the first valve according to the pressure measured by the first pressure gauge and control the second valve according to the pressure measured by the second pressure gauge.
